(19) United States
(12) Patent Application Publication
(10) Pub. No.: US 2026/0023377 A1
(43) Pub. Date: Jan. 22, 2026

(54) SWITCH SYSTEM

(71) Applicants: TOYOTA JIDOSHA KABUSHIKI KAISHA, Toyota-shi Aichi-ken (JP); DENSO CORPORATION, Kariya-city Aichi-pref (JP)

(72) Inventors: Shota HIGASHIHARA, Anjo-shi Aichi-ken (JP); Mitsuyo OMURA, Kariya-city Aichi-pref (JP)

(73) Assignees: TOYOTA JIDOSHA KABUSHIKI KAISHA, Toyota-shi Aichi-ken (JP); DENSO CORPORATION, Kariya-city Aichi-pref (JP)

(21) Appl. No.: 19/270,607

(22) Filed: Jul. 16, 2025

(30) Foreign Application Priority Data
Jul. 18, 2024 (JP) 2024-114989

(51) Int. Cl. G05B 23/02; G01R 31/00; G01R 31/327

(52) U.S. Cl. CPC G05B 23/0264; G01R 31/006; G01R 31/327

(57) ABSTRACT

In a switch system that stores, when a switch is placed in an ON-stuck state during IG-ON of a vehicle, information on the ON-sticking therein even after IG-OFF, the following occurs. When the next trip after the IG-OFF is performed in a state in which it is determined that the switch is in an ON-stuck state and the information on the ON-sticking is stored in the storage unit and when it is determined that an ON signal of the switch is not generated, the ON-sticking determination of the switch is removed. As a result, it becomes possible to optimize control in the next trip after the ON-sticking determination is performed.

### CROSS-REFERENCE TO RELATED APPLICATION

This application claims priority to Japanese Patent Application No. 2024-114989 filed on Jul. 18, 2024. The disclosure of the above-identified application, including the specification, drawings, and claims, is incorporated by reference herein in its entirety.

### BACKGROUND

### 1. Technical Field

The present disclosure relates to a switch system including a switch for operating an in-vehicle apparatus or the like. In particular, the present disclosure relates to control when the switch is in an ON-stuck state.

### 2. Description of Related Art

In general, in a vehicle cabin of a vehicle, various switches as represented by a switch for operating an air conditioning apparatus are arranged. As an example of a switch of this type, a switch that outputs an ON signal when a pushing operation is performed and outputs an OFF signal when the pushing operation is released has been known.

However, as disclosed in Japanese Unexamined Patent Application Publication No. 2020-162370 (JP 2020-162370 A), for example, a so-called ON-stuck state in which an ON signal from a switch on which an operation (pushing operation) has been performed continues to be output after the operation is released may occur. The ON-stuck state as above may occur not only in a physical switch (a switch that mechanically moves by a pushing operation) but also in a touch-screen switch.

When the switch is a physical switch, examples of the cause of the ON-stuck state of the switch include an example in which the switch cannot recover to its original position due to being caught in another member (a frame body that surrounds the switch and the like) when the switch is pushed and an example in which a liquid (a drink or the like) is spilled around the switch and, when liquid that has remained as a result of moisture of the liquid evaporating has viscosity, the switch (pushed switch) cannot recover to its original position due to the viscosity. For both of a physical switch and a touch-screen switch, examples of the cause of the ON-stuck state include an example in which the state in which the switch is ON is maintained due to electrical malfunction inside the switch.

### SUMMARY

However, in these types of switches, a specific proposal regarding the optimization of the control when the ON-stuck state of the switch is resolved in the next trip (a state in which IG-ON is performed after IG-OFF is performed) after the ON-sticking determination is performed has not hitherto been given, and there has been room for improvement in terms of optimizing control in such a situation.

The present disclosure has been made in view of the point above, and an object thereof is to provide a switch system capable of optimizing control in a next trip after ON-sticking determination is performed.

A solution of the present disclosure for achieving the object is directed to a switch system including an operation situation determination unit, an ON-sticking determination unit, and a storage unit. The operation situation determination unit is configured to acquire a state signal when a switch is operated. The ON-sticking determination unit is configured to determine an ON-stuck state of the switch that is a state in which the state signal continues to be output to the operation situation determination unit. The storage unit is configured to store, when the switch is placed in the ON-stuck state during IG-ON of a vehicle, information on the ON-sticking in the storage unit even after IG-OFF. In the switch system, when the next trip after the IG-OFF is performed in a state in which the ON-sticking determination unit has determined that the switch is in an ON-stuck state and the information on the ON-sticking is stored in the storage unit and when the operation situation determination unit determines that the state signal is not generated, the ON-sticking determination of the switch by the ON-sticking determination unit is removed.

By this particular matter, when the switch is placed in an ON-stuck state and the ON-sticking determination unit determines that the switch is in an ON-stuck state, the storage unit stores therein the information on the ON-sticking even after IG-OFF of the vehicle is performed. Then, in the next trip when IG-ON is performed, the ON-sticking determination of the switch by the ON-sticking determination unit is continued when the operation situation determination unit determines that a state signal is generated (the ON-stuck state of the switch is continued). Meanwhile, the ON-sticking determination of the switch by the ON-sticking determination unit is removed when the operation situation determination unit determines that a state signal is not generated as a result of the ON-stuck state of the switch being resolved. As a result, the operation state of the switch is determined in accordance with the state signal when the switch is operated after the above. As above, it becomes possible to optimize control in the next trip after the ON-sticking determination is performed.

In the present disclosure, when the next trip after IG-OFF is performed in a state in which it is determined that the switch is in an ON-stuck state and the information on the ON-sticking is stored and when it is determined that a state signal is not generated, the ON-sticking determination of the switch is removed. As a result, it becomes possible to optimize control in the next trip after the ON-sticking determination is performed.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a view showing each switch of an air conditioner operation unit according to an embodiment;

FIG. 2 is a block diagram showing a schematic configuration of an air conditioner system according to the embodiment;

FIG. 3 is a flowchart diagram showing a procedure of air conditioning control in accordance with a switch operation in the embodiment;

FIG. 4A is one example of a timing chart diagram showing the relationship between the switch press-down state and the switch determination in accordance therewith in the embodiment;

FIG. 4B is another example of a timing chart diagram showing the relationship between the switch press-down state and the switch determination in accordance therewith in the embodiment;

FIG. 4C is another example of a timing chart diagram showing the relationship between the switch press-down state and the switch determination in accordance therewith in the embodiment; and

FIG. 4D is one example of a timing chart diagram showing the relationship between the switch press-down state and the switch determination in accordance therewith in related art.

### DETAILED DESCRIPTION OF EMBODIMENTS

An embodiment of the present disclosure is described below with reference to the drawings. In the present embodiment, a case in which a switch system according to the present disclosure is applied as a switch system including a switch for operating an air conditioning apparatus of a battery electric vehicle is described. In the present embodiment, the switch is a physical switch, and description is made with an example in which the switch outputs an ON signal when a press-down operation is performed thereon and outputs an OFF signal when the press-down operation is released. The switch system according to the present disclosure is not limited to being applied to a battery electric vehicle and can also be applied to other vehicles (a conventional vehicle, a hybrid electric vehicle, a plug-in hybrid electric vehicle, a fuel cell electric vehicle, and the like).

### Description of Air Conditioner Operation Unit

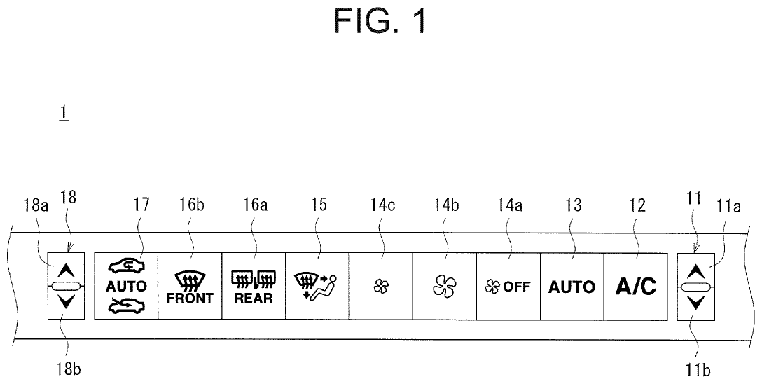

FIG. 1 is a view showing each switch of an air conditioner operation unit 1 according to the present embodiment. The air conditioner operation unit 1 is arranged on an instrument panel in a vehicle cabin. When a passenger performs a press-down (pushing) operation of the switches, control of an air conditioning apparatus (air conditioner unit) by an air conditioner electronic control unit (ECU) described later is performed in accordance with the operation.

As a plurality of switches included in the air conditioner operation unit 1 shown in FIG. 1, a driver-seat-side setting temperature changing switch 11, an air conditioner switch 12, an auto-switch 13, an OFF switch 14a, an air volume increase switch 14b, an air volume reduction switch 14c, a blowout mode switch 15, a rear window defogger switch (also serving as a mirror heater switch) 16a, a windshield defroster switch 16b, an indoor air and outdoor air switching switch 17, and a passenger-seat-side setting temperature changing switch 18 are included in the order from the right side in the drawing. The driver-seat-side setting temperature changing switch 11 and the passenger-seat-side setting temperature changing switch 18 include a corresponding one of setting temperature UP switches 11a, 18a and a corresponding one of setting temperature DOWN switches 11b, 18b.

The operation of the air conditioner unit when a press-down operation (an operation of pushing in a direction orthogonal to the plane of the paper in FIG. 1) is performed on the switches 11 to 18 is well known, and hence description here is omitted. The various switches included in the air conditioner operation unit 1 are not limited to those described above, and a synchronization switch for linking the driver-seat-side setting temperature and the passenger-seat-side setting temperature to each other, a so-called direct instruction switch that gives direct instruction regarding each setting temperature, and a relative instruction switch for raising or dropping the temperature in the vehicle cabin from the current temperature, and the like.

### Schematic Configuration of Air Conditioner System

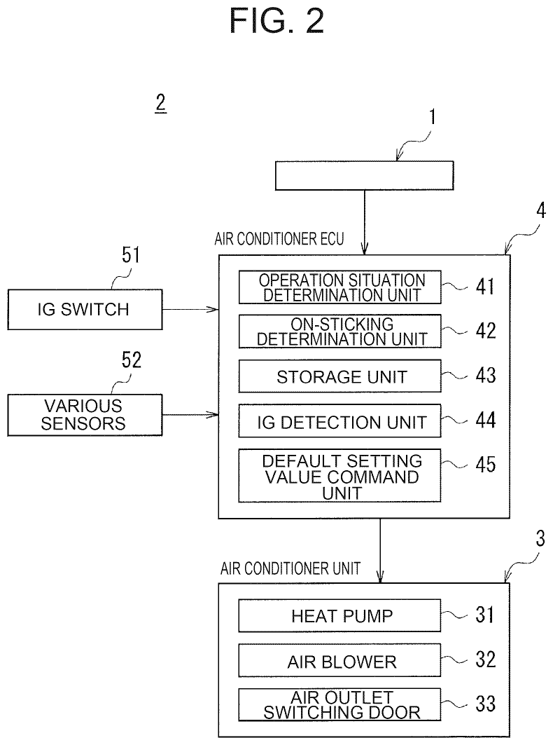

FIG. 2 is a block diagram showing a schematic configuration of an air conditioner system 2 according to the present embodiment. As shown in FIG. 2, the air conditioner system 2 includes the air conditioner operation unit 1 including the switches 11 to 18 (see FIG. 1) described above, an air conditioner unit 3, and an air conditioner ECU 4.

The air conditioner unit 3 is configured to blow out conditioned air of which temperature and humidity have been adjusted into the vehicle cabin from air outlets. The air 20 conditioner unit 3 is configured to include a heat pump 31, an air blower 32, air outlet switching doors 33, and the like.

The heat pump 31 includes an electric compressor, an outdoor heat exchanger, an indoor heat exchanger, an expansion valve, and the like, and a circulation route of a refrigerant in accordance with an air conditioning request in the vehicle cabin is formed, for example. The electric compressor is provided in order to circulate the refrigerant in the circulation route. The electric compressor is actuated by electricity from a battery and is configured such that the rotation speed is adjustable by inverter control, for example. In a conventional vehicle and the like in which an engine is installed, the compressor may be a mechanical compressor and may be actuated by receiving motive power of the engine. The outdoor heat exchanger is disposed in a motor compartment, and the indoor heat exchanger is disposed in an air blow duct (not shown). The expansion valve reduces the pressure of the refrigerant circulated in the circulation route.

The air blower 32 is configured to selectively take in outdoor air and indoor air and send out the outdoor air and the indoor air to an air blow duct. The air blower 32 is actuated by electricity from the battery and is configured such that the rotation speed is adjustable.

At the time of a cooling operation, the outdoor heat exchanger functions as a condenser and the indoor heat exchanger functions as an evaporator. As a result, the blown air is cooled by the indoor heat exchanger. At the time of a heating operation, the indoor heat exchanger functions as a condenser and the outdoor heat exchanger functions as an evaporator. As a result, the blown air is heated by the indoor heat exchanger. A heat exchanger for heating may be arranged in the air blow duct besides the indoor heat exchanger, and the blown air that has been dehumidified in the indoor heat exchanger may be heated by the heat exchanger for heating. In a conventional vehicle and the like in which an engine is installed, heating inside the vehicle cabin is performed with use of the heat of an engine coolant.

A plurality of air outlets is provided in a downstream end of the air blow duct, and the air outlet switching doors 33 are provided on these air outlets. The air outlets include a face air outlet that blows out the conditioned air toward the upper body of the passenger in the vehicle cabin, a foot air outlet that blows out the conditioned air toward the feet of the passenger in the vehicle cabin, and a defroster air outlet that blows out the conditioned air toward an inner surface of a windshield.

The air conditioner ECU 4 is provided in order to control the air conditioner unit 3. An ignition (IG) switch 51 and various sensors 52 are connected to the air conditioner ECU 4 by signal lines. As a result, an ON signal (IG-ON signal) and an OFF signal (IG-OFF signal) of the IG switch 51, sensing signals from the various sensors 52 are input to the air conditioner ECU 4. Examples of the various sensors 52 include a vehicle-cabin temperature sensor, an outdoor-air temperature sensor, and a sunlight sensor.

In the air conditioner ECU 4 (more specifically, a ROM of the air conditioner ECU 4), a control program that performs various control of the air conditioner unit 3 is stored.

The air conditioner ECU 4 includes, as function units thereof, an operation situation determination unit 41, an ON-sticking determination unit 42, a storage unit 43, an IG detection unit 44, and a default setting value command unit 45. Each of the function units, that is, the operation situation determination unit 41, the ON-sticking determination unit 42, the IG detection unit 44, and the default setting value command unit 45 is realized by the control program stored in the ROM of the air conditioner ECU 4. The storage unit 43 is realized by a backup non-volatile memory (RAM) that stores therein information even after IG-OFF is performed.

The operation situation determination unit 41 acquires a state signal when any of the switches in the air conditioner operation unit 1 is operated. For example, when a press-down operation of the setting temperature UP switch 11a of the driver-seat-side setting temperature changing switch 11 is performed, an ON signal thereof (an ON signal of the setting temperature UP switch 11a) is input to the operation situation determination unit 41 of the air conditioner ECU 4. For example, when a press-down operation of the setting temperature UP switch 11a of the driver-seat-side setting temperature changing switch 11 is released, an OFF signal thereof (an OFF signal of the setting temperature UP switch 11a) is input to the operation situation determination unit 41 of the air conditioner ECU 4. When the press-down operation of other switches is performed or released, an ON signal or an OFF signal is similarly input to the operation situation determination unit 41 of the air conditioner ECU 4 as well.

The ON-sticking determination unit 42 determines that a switch is in an ON-stuck state when an ON signal (state signal) continues to be input to the operation situation determination unit 41 from the switch. For example, when an ON signal continues to be output from the setting temperature UP switch 11a of the driver-seat-side setting temperature changing switch 11 for a predetermined amount of time (for example, for 5 seconds) and the ON signal continues to be input to the operation situation determination unit 41, it is determined that the setting temperature UP switch 11a is in an ON-stuck state. The value of the predetermined amount of time is not limited to the above. When an ON signal continues to be output from other switches for a predetermined amount of time, it is determined that the switch that is outputting the ON signal is in an ON-stuck state as well. Information on the result of the determination by the ON-sticking determination unit 42 is output to the storage unit 43 and the default setting value command unit 45. A feature of the ON-sticking determination unit 42 is that the determination that a switch is in an ON-stuck state is removed when an OFF signal is input to the operation situation determination unit 41 from the switch that has been determined to be in an ON-stuck state when the next trip caused by IG-ON after IG-OFF of the vehicle is performed.

The storage unit 43 stores therein previous setting values of the air conditioning control and information on the ON-sticking of the switch. The storage of the previous setting values of the air conditioning control means to store information on the set air volume and the setting temperature immediately before IG-OFF even when IG-OFF is performed when the air conditioner unit 3 is in actuation during the IG-ON of the vehicle. The storage of the information on the ON-sticking of the switch means to store, when the ON-sticking determination unit 42 determines that there is a switch in the ON-stuck state during the IG-ON of the vehicle, information indicating that the switch is in an ON-stuck state. The information above is stored even at the start of the next trip caused by the IG-ON after the IG-OFF of the vehicle.

An ON signal and an OFF signal of the IG switch 51 are input to the IG detection unit 44, and the IG detection unit 44 outputs information thereof to the default setting value command unit 45.

Signals from the ON-sticking determination unit 42 and the IG detection unit 44 can be input to the default setting value command unit 45. When the ON-sticking determination unit 42 determines that a switch is in an ON-stuck state while the state of IG-ON is maintained, a default setting value command signal is transmitted to equipment that is the target of the switch (the switch in the ON-stuck state) as a command signal. The default setting value is zero, for example, for the air volume blown by the air blower 32, and is 25° C., for example, as the setting temperature of the conditioned air in the heat pump 31. In other words, when the air volume increase switch 14b or the air volume reduction switch 14c is placed in an ON-stuck state, the air volume blown by the air blower 32 is set to zero (the stopping of the air blower 32). When the setting temperature UP switch 11a or the setting temperature DOWN switch 11b of the driver-seat-side setting temperature changing switch 11 is placed in an ON-stuck state, the driver-seat-side setting temperature is set to 25° C. Similarly, when the setting temperature UP switch 18a or the setting temperature DOWN switch 18b of the passenger-seat-side setting temperature changing switch 18 is placed in an ON-stuck state, the passenger-seat-side setting temperature is set to 25° C. In embodiments, these values can be freely set and may be values that can significantly reduce electricity consumption.

When the next trip caused by IG-ON after IG-OFF is started in a state in which information indicating that a switch is in an ON-stuck state is stored in the storage unit 43, the default setting value command unit 45 transmits a default setting value command signal to the air conditioner unit 3 as a command signal to equipment that is the target of the switch (the switch in the ON-stuck state) as well. In other words, at the time of IG-ON in a situation in which a switch is in an ON-stuck state, the equipment that is the target of the switch (the switch in the ON-stuck state) is controlled by the default setting value as well.

By the system configuration as above, the switch system according to the present disclosure is configured by each function unit in the air conditioner operation unit 1 and the air conditioner ECU 4 described above.

### Air Conditioning Control

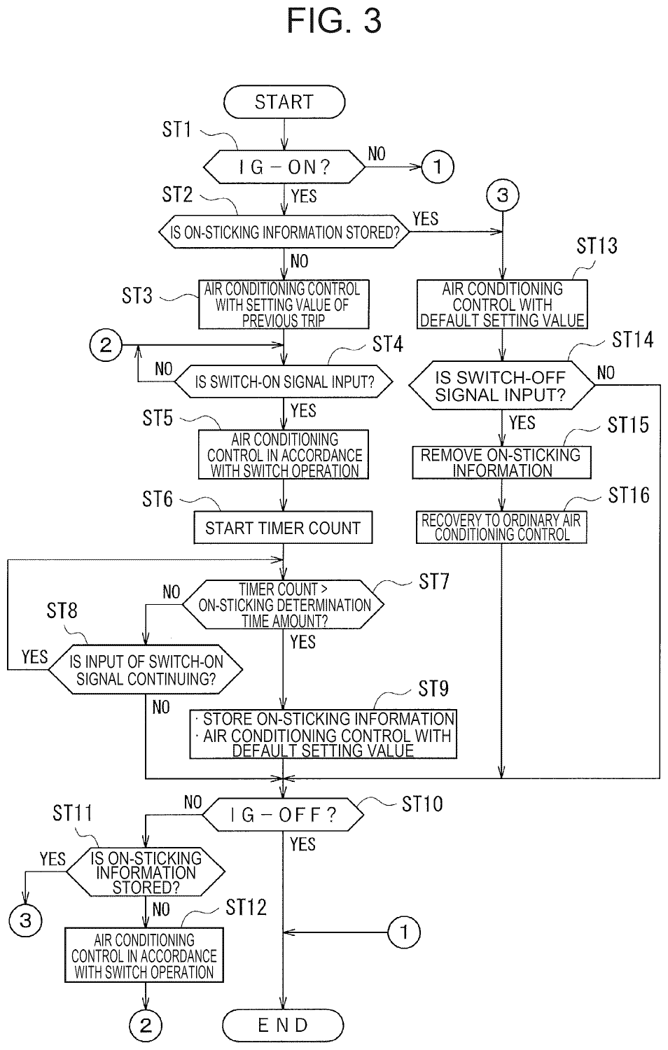

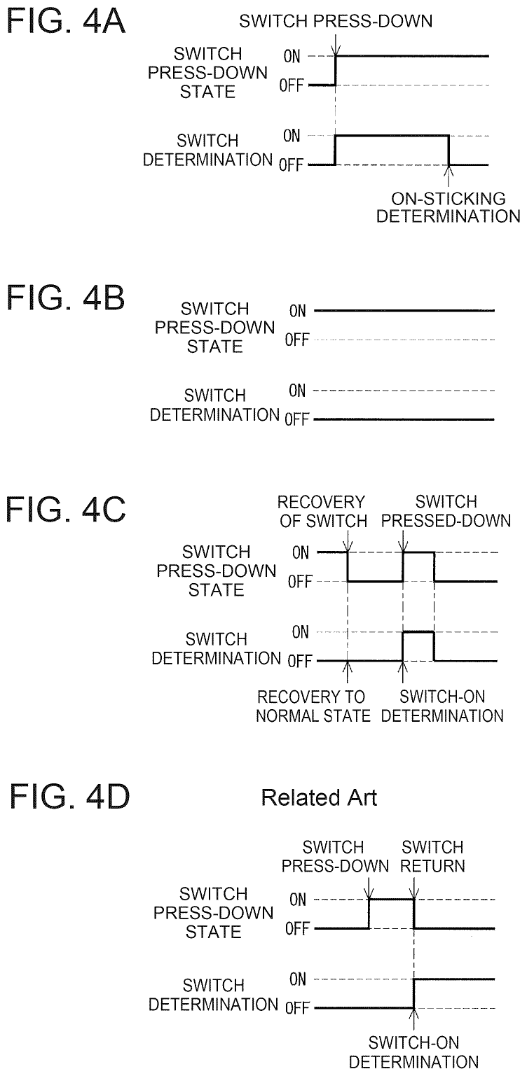

Next, air conditioning control when a switch operation is performed in the configuration described above is described with reference to FIG. 3 and FIG. 4A to FIG. 4C. FIG. 3 is a flowchart showing a procedure of air conditioning control in accordance with a switch operation in the embodiment. FIG. 4A to FIG. 4C are timing charts showing the relationship between the switch press-down state and the switch determination in accordance therewith. Description is made below for one switch (for example, the air volume increase switch 14b) out of the switches 11 to 18.

First, in Step ST1, it is determined whether IG-ON is performed (whether the IG detection unit 44 has received an ON signal from the IG switch 51). When IG-ON is not performed and it is determined to be NO in Step ST1, the process ends as is.

Meanwhile, when IG-ON is performed and it is determined to be YES in Step ST1, the process proceeds to Step ST2, and it is determined whether information on the ON-sticking is stored in the storage unit 43. When the ON-stuck state is not occurring in any of the switches and information on the ON-sticking is not stored in the storage unit 43, it is determined to be NO in Step ST2, and the process proceeds to Step ST3. In Step ST3, air conditioning control using previous setting values of the air conditioning control (the set air volume and the setting temperature in the previous trip) stored in the storage unit 43 is started, and the process proceeds to Step ST4.

In Step ST4, it is determined whether an ON signal (switch-ON signal) is input (input to the operation situation determination unit 41) from a switch (for example, the air volume increase switch 14b) as a result of a press-down operation being performed on the switch.

When it is determined to be YES in Step ST4 as a result of an ON signal being input from the switch, the process proceeds to Step ST5, and air conditioning control in accordance with the switch operation is performed. For example, when a press-down operation is performed on the air volume increase switch 14b, the air volume of the air blower 32 is increased by one level. At this time, when the switch is held down, air conditioning control in accordance with the operation is performed for every predetermined amount of time. For example, when the air volume increase switch 14b is held down, the air volume of the air blower 32 is increased by one level every predetermined amount of time.

When the air conditioning control in accordance with the switch operation is started as above, the count of a timer included in the air conditioner ECU 4 is started in Step ST6, and the process proceeds to Step ST7. In Step ST7, it is determined whether the count of the timer has exceeded a predetermined ON-sticking determination time amount. In other words, it is determined whether a state in which the ON signal from the switch continues to be input for a predetermined amount of time is obtained. The ON-sticking determination time amount can be freely set.

When the count of the timer has not exceeded the predetermined ON-sticking determination time amount yet and it is determined to be NO in Step ST7, the process proceeds to Step ST8, and it is determined whether the input of the ON signal from the switch is continued. When the input of the ON signal from the switch is stopped, it is determined to be NO in Step ST8, and the process proceeds to Step ST10. Meanwhile, when the input of the ON signal from the switch is continued, it is determined to be YES in Step ST8, and the process returns to Step ST7.

When the input of the ON signal from the switch is not stopped and the amount of time (the count of the timer) for which the ON signal continues to be input exceeds the ON-sticking determination time amount, it is determined to be YES in Step ST7, and the process proceeds to Step ST9. In Step ST9, the ON-sticking determination unit 42 determines that the switch is in an ON-stuck state, the information on the ON-sticking is stored in the storage unit 43, and a default setting value command signal is transmitted to the air conditioner unit 3 from the default setting value command unit 45. FIG. 4A shows the relationship between the switch press-down state and the switch determination in accordance therewith at this time. In other words, as a result of the switch press-down state exceeding a predetermined amount of time (ON-sticking determination time amount), it is determined that the switch is in an ON-stuck state as the switch determination. When it is determined that the switch is in an ON-stuck state as above, the air conditioning control with a default setting value is performed. For example, when it is determined that the air volume increase switch 14b is in an ON-stuck state, the air volume blown by the air blower 32 is set to zero (the air blower 32 is stopped). For example, when it is determined that the setting temperature UP switch 11a of the driver-seat-side setting temperature changing switch 11 is in an ON-stuck state, the driver-seat-side setting temperature is set to 25° C. After the air conditioning control with a default setting value is started as above, the process proceeds to Step ST10.

In Step ST10, it is determined whether IG-OFF is performed (whether the IG detection unit 44 has received an OFF signal from the IG switch 51). When IG-OFF is performed and it is determined to be YES in Step ST10, the air conditioning control is stopped and the control ends. Meanwhile, when IG-OFF is not performed (the state of IG-ON is maintained) and it is determined to be NO in Step ST10, the process proceeds to Step ST11, and it is determined whether the information on the ON-sticking is stored in the storage unit 43. In other words, it is determined to be YES (it is determined that the switch is in an ON-stuck state) in Step ST7, and it is determined whether information on the ON-sticking is stored in the storage unit 43 by Step ST9. When information on the ON-sticking is not stored in the storage unit 43 and it is determined to be NO in Step ST11, the process proceeds to Step ST12, and the air conditioning control in accordance with the switch operation is performed. Meanwhile, when the information on the ON-sticking is stored in the storage unit 43 and it is determined to be YES in Step ST11, the process proceeds to Step ST13.

In Step ST13, air conditioning control with a default setting value based on a default setting value command signal transmitted to the air conditioner unit 3 from the default setting value command unit 45 is performed (when air conditioning control with a default setting value is performed in Step ST9, the air conditioning control is continued). Then, in Step ST14, it is determined whether an OFF signal (switch-OFF signal) is input (input to the operation situation determination unit 41) from the switch that has been determined to be in an ON-stuck state.

When an OFF signal is not input to the operation situation determination unit 41 from the switch determined to be in an ON-stuck state and it is determined to be NO in Step ST14, the process returns to Step ST10. Meanwhile, when an OFF signal is input to the operation situation determination unit 41 from the switch determined to be in an ON-stuck state and it is determined to be YES in Step ST14, the process proceeds to Step ST15, and the information on the ON-sticking stored in the storage unit 43 is removed. In other words, the switch that has been in an ON-stuck state recovers to its original position, and hence the information on the ON-sticking is removed. Then, the process proceeds to Step ST16 and recovery to ordinary air conditioning control in accordance with the operation of the switch is made.

When IG-OFF is performed in Step ST10 while a state in which it is determined that the switch is in an ON-stuck state and the information on the ON-sticking is stored in the storage unit 43 in Step ST9 is maintained, the following occurs. Specifically, in the next trip (next routine) caused by subsequent IG-ON, it is determined to be YES in Step ST1, and it is determined to be YES in Step ST2. As a result, air conditioning control with a default setting value based on a default setting value command signal transmitted to the air conditioner unit 3 from the default setting value command unit 45 is performed. When an OFF signal is not input to the operation situation determination unit 41 from the switch determined to be in an ON-stuck state in Step ST14, the process proceeds to Step ST10. FIG. 4B shows the relationship between the switch press-down state and the switch determination in accordance therewith at this time. In other words, although the switch press-down state is maintained because the switch is in an ON-stuck state, the switch determination is OFF (a state that does not accept a switch operation) because it is stored that the switch is an ON-stuck state.

When an OFF signal is input to the operation situation determination unit 41 from the switch determined to be in an ON-stuck state, the information on the ON-sticking stored in the storage unit 43 is removed in Step ST15. In other words, the switch that has been in an ON-stuck state recovers to its original position, and hence the information on the ON-sticking is removed. Then, the process proceeds to Step ST16 and recovery to ordinary air conditioning control in accordance with the operation of the switch is made. FIG. 4C shows the relationship between the switch press-down state and the switch determination in accordance therewith at this time. In other words, as a result of the switch recovering to its original position, it is determined that recovery to a normal state has been made as the switch determination. When the press-down operation of the switch is subsequently performed, it is determined that the switch is turned ON in accordance therewith as the switch determination. The operation above is repeated.

### Effects of Embodiment

As described above, in the present embodiment, when the next trip after IG-OFF is performed in a state in which the ON-sticking determination unit 42 has determined that a switch is in an ON-stuck state and information on the ON-sticking is stored in the storage unit 43 and when an OFF signal is input from the switch (when it is determined that a state signal is not generated), the information on the ON-sticking stored in the storage unit 43 is removed (the ON-sticking determination of the switch is removed). As a result, it becomes possible to optimize control in the next trip after the ON-sticking determination is performed.

Comparison with Related-Art Switch

Here, a comparison with a general related-art switch is described. Here, points where the switch system according to the present embodiment has been able to solve problems that have occurred in three types of switches as general related-art switches are described.

First, comparison with a so-called non-latching switch as a first related-art switch is described. The non-latching switch is applied to a drive mode selecting switch, and idle stop switch, and the like in a vehicle, for example. When IG-ON is performed after IG-OFF is performed, the non-latching switch cancels the switch state immediately before the IG-OFF (performs switch-OFF), and the non-latching switch is known as a switch that does not inherit the settings at the time of IG-OFF. However, when this type of switch is applied as a switch for air conditioning, air conditioning settings (the blown air volume and the setting temperature) at the time of IG-OFF are not inherited, and there is the inconvenience of needing to set the air conditioning settings every time the IG-ON is performed. In the present embodiment, as described in Step ST3 in the flowchart described above, the air conditioning control using the previous setting values of the air conditioning control stored in the storage unit 43 is performed. Therefore, air conditioning settings (the blown air volume and the setting temperature) at the time of IG-OFF can be inherited, and the inconvenience of needing to set the air conditioning settings every time the IG-ON is performed does not occur.

Comparison with an OFF edge determination switch as a second related-art switch is described. The OFF edge determination switch is known as a switch that performs switch-ON determination when press-down operation is released after the press-down operation is performed on the switch. FIG. 4D shows the relationship between the switch press-down state and the switch determination in accordance therewith in the OFF edge determination switch. However, when this type of switch is placed in an ON-stuck state, the switch-ON determination is not performed because the press-down state of the switch is not released. As a result, the ON-sticking determination is not performed either. In other words, it cannot be determined that the switch is in an ON-stuck state. In the present embodiment, the switch-ON determination is performed when a press-down operation is performed on the switch, and hence the ON-sticking determination of the switch can be satisfactorily performed.

As a third related-art switch, a switch that determines that the switch is broken when an ON signal from the switch continues to be output for a predetermined amount of time has been known. However, in this switch, when an object in the vehicle cabin is in continuous contact with the switch, it is determined that the switch is broken even when the switch is not broken, and there is a fear that excessive measures may be taken in order to respond thereto. In the present embodiment, even when it is temporarily determined that the switch is in an ON-stuck state, return to a normal state is performed when an OFF signal is output from the switch thereafter. Therefore, the problem of the switch can be solved.

### OTHER EMBODIMENTS

The present disclosure is not limited to the embodiments described above, and all modifications and applications included in the scope of the claims and a scope equivalent to the scope are possible.

For example, in the present embodiment, application as a switch system including a switch for operating an air conditioning apparatus (air conditioner unit) of a vehicle (battery electric vehicle) has been described. The present disclosure is not limited to the above and can be applied to switch systems included in various apparatuses.

In the embodiment, the switch is a physical switch and description is made with an example in which the switch outputs an ON signal when an press-down operation is performed thereon and outputs an OFF signal when the press-down operation is released. The present disclosure is not limited to the above and may be a physical switch of which output voltage is 0 V when a pushing operation is not performed thereon and which outputs a predetermined voltage (for example, 5 V) when a pushing operation is performed thereon. A physical switch including a function of determining an ON-stuck state may be applied. The present disclosure is not limited to a physical switch and is applicable to a touch-screen switch.

The present disclosure is applicable to control when a switch in a switch system for operating an air conditioning apparatus of a vehicle is placed in an ON-stuck state.

What is claimed is:

1. A switch system comprising:
an operation situation determination unit configured to acquire a state signal when a switch is operated;
an ON-sticking determination unit configured to determine an ON-stuck state of the switch that is a state in which the state signal continues to be output to the operation situation determination unit; and
a storage unit configured to store, when the switch is placed in the ON-stuck state during IG-ON of a vehicle, information on the ON-sticking in the storage unit even after IG-OFF, wherein, when a next trip after the IG-OFF is performed in a state in which the ON-sticking determination unit has determined that the switch is in an ON-stuck state and the information on the ON-sticking is stored in the storage unit and when the operation situation determination unit determines that the state signal is not generated, the ON-sticking determination of the switch by the ON-sticking determination unit is removed.
